(19) United States
(12) Patent Application Publication
(10) Pub. No.: US 2026/0275505 A1
(43) Pub. Date: Sep. 17, 2026

(54) METHOD FOR PRODUCING DIAMOND THIN FILM AND APPARATUS FOR PRODUCING DIAMOND THIN FILM

(71) Applicant: NISSIN ELECTRIC CO., LTD., Kyoto (JP)

(72) Inventors: Ryota ANDO, Kyoto (JP); Satoru NAGAMACHI, Kyoto (JP); Natsuo TATSUMI, Kyoto (JP)

(73) Assignee: NISSIN ELECTRIC CO., LTD., Kyoto (JP)

(21) Appl. No.: 19/163,810

(22) PCT Filed: Jun. 6, 2024
(86) PCT No.: PCT/JP2024/020734

§ 371 Date: Sep. 9, 2025

(30) Foreign Application Priority Data
Jul. 5, 2023 (JP) 2023-110497

(51) Int. Cl. C23C 16/27; C23C 16/505

(52) U.S. Cl. CPC C23C 16/272; C23C 16/505

(57) ABSTRACT

Provided is a method for producing a diamond thin film, which includes supplying a raw material gas containing C, H, and O into a vacuum vessel in which a base material is disposed, generating inductively coupled plasma in the vacuum vessel by flowing high-frequency current through an antenna disposed inside or outside the vacuum vessel, the antenna including a conductor element and a capacitive element electrically connected to each other in series, and synthesizing a diamond thin film on the base material by a plasma CVD method using a generated inductively coupled plasma. Plasma characteristics when synthesizing the diamond thin film include: an electron temperature of 1.0 eV or more and 2.0 eV or less, an electron density of 1.0×10¹¹ cm⁻³ or more and 1.0×10¹²cm⁻³ or less, and an ion saturation current of 1.0×10⁻⁴ A or more and 1.0×10⁻² A or less.

### TECHNICAL FIELD

The present invention relates to a method for producing diamond thin film and an apparatus for producing diamond thin film that are synthesized using a plasma CVD method.

### DESCRIPTION OF RELATED ART

Conventionally, as methods for producing diamond thin film synthesized using CVD method, methods for producing diamond thin film using a filament CVD apparatus, a microwave resonator type plasma CVD apparatus, a microwave surface wave plasma CVD apparatus (e.g., Patent Document 1), or a high-frequency inductively coupled (RF-ICP) type plasma CVD apparatus using a coil-shaped electrode (e.g., Patent Document 2) are known.

In the production method using a filament CVD apparatus, a high melting point metal wire is installed above the base material on which the diamond thin film is formed, and the diamond thin film is produced by decomposing the raw material gas with thermoelectrons released according to heating of this metal wire.

Further, in production methods using a plasma CVD apparatus utilizing microwaves or a plasma CVD apparatus utilizing high frequency, plasma containing raw material gas is generated by applied high-frequency current, and the diamond thin film is synthesized with the activated gas.

In these production methods, it is known that active atomic hydrogen is mainly generated in the plasma, and by its action, non-diamond components of sp1 bonding or sp2 bonding are removed, and diamond components of sp3 bonding may mainly grow.

### RELATED ART DOCUMENTS(S)

### Patent Document

Patent Document 1: Japanese Patent Application Laid-Open Publication No. 2013-40408.

Patent Document 2: Japanese Patent Application Laid-Open Publication No. 2003-55087.

### SUMMARY OF INVENTION

### Technical Problem

However, in the case of synthesizing diamond using the above plasma CVD apparatus, diamond may only be synthesized in a small area due to constraints in the apparatus configuration. For example, in the case of lengthening the filament to synthesize diamond in a large area, there is a risk that the filament cannot withstand its own weight and may break during plasma generation. Further, microwaves such as 2.45 GHz or 915 MHz are used, but the plasma size could not be enlarged due to problems with resonance wavelength.

Furthermore, in synthesizing diamond thin film, graphite or diamond-like carbon (DLC) is synthesized simultaneously with diamond, and the film quality of the diamond thin film is deteriorated. As a result of intensive studies, the present inventor found for the first time that deterioration of the film quality of diamond thin film may be suppressed in the case of electron temperature, electron density, and ion saturation current, which indicate plasma characteristics in the case of synthesizing diamond thin film, being within predetermined ranges.

The present invention has been made to solve the above problems, and its main object is to synthesize diamond thin film over a wider area and to suppress deterioration of the film quality of diamond thin film.

### Solution to Problem

That is, the method for producing a diamond thin film according to the present invention is a method for producing a diamond thin film including: supplying a raw material gas containing C, H, and O into a vacuum vessel in which a base material is disposed, generating inductively coupled plasma in the vacuum vessel by flowing high-frequency current through an antenna disposed inside or outside the vacuum vessel, the antenna including a conductor element and a capacitive element electrically connected to each other in series, and synthesizing a diamond thin film on the base material by a plasma CVD method using a generated inductively coupled plasma. Plasma characteristics when synthesizing the diamond thin film include: an electron temperature of 1.0 eV or more and 2.0 eV or less, an electron density of 1.0×10¹¹cm⁻³ or more and 1.0×10¹² cm⁻³ or less, and an ion saturation current of 1.0×10⁻⁴ A or more and 1.0×10⁻² A or less.

With such a configuration, since an antenna having conductor elements and capacitive elements electrically connected in series with each other is used, compared to a configuration using a conventional plasma CVD apparatus, uniform plasma is generated in the longitudinal direction of the antenna, and diamond thin film with a wider area may be synthesized. Further, in the case of the plasma characteristics being within the above numerical ranges, since the diamond thin film is synthesized in a state where the electron quantity and electron temperature are appropriate, deterioration of the film quality of the diamond thin film may be prevented. Specifically, in the case of the electron temperature becoming a value greater than the upper limit value, electron collision with the base material increases and the temperature of the base material rises excessively, and there is a possibility that graphite may be synthesized. On the other hand, in the case of the electron temperature becoming a value less than the lower limit value, sufficient dissociation of the raw material gas has not progressed, and the synthesized thin film becomes a DLC film with many sp bonding or sp2 bonding. Thus, electron temperature needs to be within the above numerical range. Further, regarding the electron density, for the same reason as the electron temperature, in order to prevent synthesis of graphite or synthesis of a DLC film, the electron density needs to be within the above numerical range.

Here, in the synthesis of the diamond thin film, ionic carbon species (C²⁺, CH₃⁺, CH⁺, etc.) exist in the plasma. As a result, two phenomena occur simultaneously: (1) secondary nuclei are generated on the diamond by ionic carbon species colliding with the growth surface, and (2) growth of the diamond thin film is inhibited by the ionic carbon species.

In order to synthesize the diamond thin film while suppressing these two phenomena, it is necessary to control the ion saturation current within the above numerical range. Specifically, in the case of the ion saturation current becoming a value greater than the upper limit value, the frequency of ionic carbon species colliding with the base material increases, and growth inhibition of the diamond thin film by the ionic carbon species becomes large. As a result, the growth rate of the diamond thin film decreases, or the film quality of the diamond thin film deteriorates. On the other hand, in the case of the ion saturation current becoming less than the lower limit value, ionic carbon species necessary for growth of the diamond thin film do not sufficiently exist on the surface of the base material, and the growth rate of the diamond thin film decreases. Thus, the ion saturation current needs to be within the above numerical range.

As a specific aspect of the antenna, one that has a linear shape and has a length of 30 cm or more in the longitudinal direction may be listed.

With such a configuration, compared to a configuration using a conventional plasma CVD apparatus, diamond thin film with a wider area may be uniformly synthesized in the longitudinal direction.

Further, as a specific aspect of the method for producing the diamond thin film, one in which the distance between the antenna and the base material is 100 mm or less may be listed.

With such a configuration, uniform plasma is generated in the longitudinal direction of the antenna within the vacuum vessel, and diamond thin film may be uniformly synthesized with respect to the longitudinal direction of the antenna.

The method for producing the diamond thin film applies a bias voltage to the base material, a negative bias voltage of −100V or less is applied to the base material, and a positive bias voltage of 100V or less is applied to the base material.

With such a configuration, by applying a bias voltage to the base material, the energy when positive ions in the plasma are incident on the base material may be controlled, and control of the crystallinity of the film formed on the surface of the base material may be performed. Specifically, by applying a negative bias voltage of −100V or less to the base material, formation of diamond growth nuclei is promoted, and by applying a positive bias voltage of 100V or less, growth of the diamond thin film may be promoted.

The raw material gas preferably further contains a noble gas that is Ar, He, or Ne. With such a configuration, among the components contained in the gas, components that are difficult to decompose, such as carbon dioxide, may be made easier to decompose.

In order to manufacture a diamond thin film using high frequency instead of microwave, the high frequency of the high-frequency current may have a frequency of 400 kHz or more and 100 MHz or less.

An apparatus for producing a diamond thin film for synthesizing a diamond thin film on a base material by a plasma CVD method using inductively coupled plasma includes: a vacuum vessel in which the base material is disposed and to which a raw material gas containing C, H, and O is supplied; an antenna disposed inside or outside the vacuum vessel and including a conductor element and a capacitive element electrically connected to each other in series, and a high-frequency power source for applying high frequency to the antenna to generate inductively coupled plasma in the vacuum vessel. Plasma characteristics in the vacuum vessel when synthesizing the diamond thin film include: an electron temperature of 1.0 eV or more and 2.0 eV or less, an electron density of 1.0×10¹¹cm⁻³ or more and 1.0×10¹²cm⁻³ or less, and an ion saturation current of 1.0×10⁻⁴ A or more and 1.0×10⁻² A or less.

With such a configuration, the same effects as the above method for producing the diamond thin film may be obtained.

### Effects of the Invention

According to the present invention configured in this manner, a diamond thin film may be synthesized over a wider area, and deterioration of the film quality of the diamond thin film may be suppressed.

### BRIEF DESCRIPTION OF THE DRAWINGS

FIG. 1 is a diagram schematically showing a configuration of a film forming apparatus according to one embodiment of the present invention.

FIG. 2 is a diagram showing a gas composition range of raw material gas supplied by the film forming apparatus and the method for producing the diamond thin film of the same embodiment.

### DESCRIPTION OF THE EMBODIMENTS

Hereinafter, a film forming apparatus and a method for producing a diamond thin film according to one embodiment of the present invention will be described with reference to the drawings. It is noted that any of the drawings shown below may be schematically drawn with appropriate omissions or exaggerations for clarity. The same reference numerals are assigned to the same components, and descriptions thereof are appropriately omitted.

### Apparatus Configuration

The film forming apparatus 100 of this embodiment is a plasma CVD apparatus that forms a diamond thin film F on a base material W by a plasma CVD method using inductively coupled plasma P.

The base material W of this embodiment is plate-shaped and composed of a material suitable for forming the diamond thin film F. The base material W may be made of materials such as glass, plastic, silicon, metals such as iron, titanium, copper, and cemented carbide, other alloy materials such as tool steel, and materials such as SiC, GaN, AlN, BN, and diamond, but is not limited thereto.

The base material W has a rectangular or circular shape in plan view. The length of the base material W may be, for example, 20 cm or more or 50 cm or more, but is not limited thereto. The base material W may also be multiple small chip-shaped base materials of, for example, approximately 1 mm, 5 mm, or 10 mm arranged with similar length or area. The base material W is not limited to a plate shape, and may be columnar, perforated, or porous. Further, the base material W may also have a complex shape such as tools like drills and end mills.

The base material W may also be subjected to surface treatments such as so-called damage treatment or seeding treatment. For example, in the case of the base material W being silicon, damage treatment or seeding treatment may be performed by immersing in alcohol together with diamond fine particles and forming irregularities on the surface by ultrasonic treatment. Further, for example, in the case of the base material W being cemented carbide, Co in the base material may be removed by immersion in an acidic solution such as nitric acid aqueous solution, or WC (tungsten carbide) particle surfaces may be treated with an alkaline solution such as diluted NaOH, and then the seeding treatment as described above may be performed.

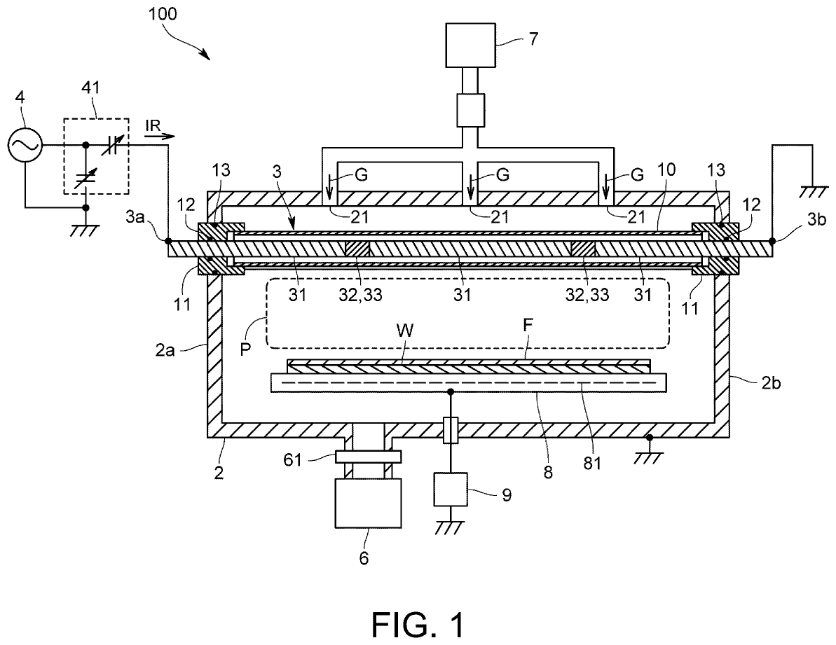

Specifically, as shown in FIG. 1, the film forming apparatus 100 includes a vacuum vessel 2 that is vacuum evacuated and into which gas G is introduced, a gas supply mechanism 7 that supplies gas G to the vacuum vessel 2, a linear antenna 3 disposed within the vacuum vessel 2, and a high-frequency power source 4 that applies high frequency to the antenna 3 to generate inductively coupled plasma P in the vacuum vessel 2. In this film forming apparatus 100, by applying high frequency from the high-frequency power source 4 to the antenna 3, high-frequency current IR flows through the antenna 3, an induced electric field is generated within the vacuum vessel 2, and inductively coupled plasma P is generated.

The vacuum vessel 2 is a metal container made of, for example, SUS or aluminum, and the interior is vacuum evacuated by a vacuum exhaust apparatus 6. The vacuum vessel 2 is electrically grounded in this example. It is noted that the vacuum exhaust apparatus 6 includes a pressure regulator 61 such as a valve that adjusts the pressure within the vacuum vessel 2. The pressure regulator 61 is controlled to adjust the pressure within the vacuum vessel 2 during plasma generation, and is configured to adjust the pressure to, for example, 7 Pa or more and 100 Pa or less.

Gas G such as raw material gas is introduced into the vacuum vessel 2 via, for example, a flow rate controller (not shown) and multiple gas introduction ports 21 arranged in a direction along the antenna 3.

Further, a base material holder 8 that holds the base material W is provided within the vacuum vessel 2, and a heater 81 that heats the base material W is provided within this base material holder 8. It is noted that the base material holder 8 may not be electrically connected to the vacuum vessel 2. The film forming apparatus 100 of this embodiment may have a function of adjusting the potential with respect to the generated inductively coupled plasma in a range of, for example, +100V to −100V by applying a bias voltage from a bias power source 9 to the base material holder 8. The applied bias voltage is, for example, a negative DC voltage, but is not limited thereto. With such bias voltage, for example, the energy when positive ions in plasma P is incident on the base material W may be controlled to perform control of crystallinity of the film formed on the surface of the base material W.

The gas supply mechanism 7 supplies gas G such as raw material gas into the vacuum vessel 2 through the gas introduction port 21. The gas supply mechanism 7 is configured to supply gas G downward from the gas introduction port 21 provided on the upper wall of the vacuum vessel 2. This gas supply mechanism 7 is configured to supply raw material gas containing at least C (carbon), H (hydrogen), and O (oxygen), and specifically is configured to supply H₂ gas, CH₄ gas, and CO₂ gas as raw material gas. It is noted that the gas supply mechanism 7 may be configured to supply any other gas as raw material gas in addition to or instead of H₂ gas, CH₄ gas, and CO₂ gas, as long as it is configured to supply raw material gas containing C, H, and O into the vacuum vessel 2.

The gas supply mechanism 7 is configured to supply H₂ gas, CH₄ gas, and CO₂ gas at arbitrary flow rates, respectively. The gas supply mechanism 7 of this embodiment is configured to adjust and supply the flow rate of each gas such that in the raw material gas configured to include H₂ gas, CH₄ gas, and CO₂ gas, the ratio of the concentration of O atoms to the total concentration of contained O atoms and H atoms (O/(O+H)) becomes, for example, 5 at % or more and 45 at % or less.

The gas supply mechanism 7 is also configured to supply catalyst gas into the vacuum vessel 2 at an arbitrary flow rate together with the raw material gas. This catalyst gas functions as a catalyst during plasma generation and promotes decomposition of the raw material gas. Specifically, the gas supply mechanism 7 is configured to supply catalyst gas such that the ratio to the total flow rate of all gases supplied into the vacuum vessel 2 (here, the total flow rate of raw material gas and catalyst gas) becomes, for example, 50% or more and 95% or less, preferably 70% or more and 90% or less. Specifically, examples of this catalyst gas include noble gases such as Ar gas, He gas, and Ne gas.

The antenna 3 is disposed above the base material W in the vacuum vessel 2 so as to extend along the surface of the base material W. In this embodiment, multiple linear antennas 3 are arranged in parallel along the base material W (e.g., substantially parallel to the surface of the base material W). In this way, plasma P with good uniformity may be generated over a wider range, and thus processing of larger base material W may be accommodated.

It is noted that the number of antennas 3 is not limited to multiple antennas, and may be only one antenna. In the case of providing multiple antennas 3, the number is preferably an even number (2, 4, 6, etc.). Further, in the case of providing multiple antennas 3, to avoid radio wave interference, the spacing between each antenna 3 is preferably 5 cm or more, more preferably 10 cm or more, and even more preferably 15 cm or more. On the other hand, to form a uniform diamond thin film F, the spacing between antennas 3 is preferably 25 cm or less.

As shown in FIG. 1, the vicinity of two ends of the antenna 3 penetrate through a pair of opposing sidewalls 2a and 2b of the vacuum vessel 2, respectively. Insulating members 11 are respectively provided at portions where two ends of the antenna 3 penetrate to the outside of the vacuum vessel 2. Two ends of the antenna 3 penetrate through each of these insulating members 11, and the penetrating parts are vacuum sealed by, for example, packing 12. The antenna 3 is supported in an electrically insulated state with respect to the opposing sidewalls 2a and 2b of the vacuum vessel 2 via these insulating members 11. The space between each insulating member 11 and the vacuum vessel 2 is also vacuum sealed by, for example, packing 13. It is noted that the material of the insulating member 11 is, for example, ceramics such as alumina, quartz, or engineering plastics such as polyphenylene sulfide (PPS) or polyether ether ketone (PEEK).

Further, the antenna 3 is a so-called LC antenna that includes an L part serving as an inductor and a C part serving as a capacitor. Specifically, this antenna 3 includes at least two tubular metallic conductor elements 31 (hereinafter, metal pipes 31), tubular insulating elements 32 (hereinafter, insulation pipes 32) provided between mutually adjacent metal pipes 31 to insulate these metal pipes 31, and capacitors 33 which are capacitive elements provided between mutually adjacent metal pipes 31 and electrically connected in series with the same. The conductor elements 31 function as L parts, and the capacitors 33 function as C parts.

In this embodiment, the number of metal pipes 31 is three, and the number of insulation pipes 32 and capacitors 33 is two each. It is noted that the antenna 3 may have a configuration having four or more metal pipes 31, and in this case, the numbers of insulation pipes 32 and capacitors 33 are both one less than the number of metal pipes 31.

The material of the metal pipe 31 is, for example, copper, aluminum, alloys thereof, stainless steel, or the like, but is not limited thereto. It is noted that the antenna 3 may be made hollow so that a coolant such as cooling water flows therein to cool the antenna 3.

The insulation pipe 32 of this embodiment is formed from a single member, but is not limited thereto. It is noted that the material of the insulation pipe 32 is, for example, alumina, fluorocarbon resin, polyethylene (PE), engineering plastics (such as polyphenylene sulfide (PPS), polyether ether ketone (PEEK)), or the like.

Furthermore, in the antenna 3, the portion located within the vacuum vessel 2 is covered by a straight tubular insulation cover (antenna protection tube) 10. Two ends of this insulation cover 10 are supported by the insulating members 11. It is noted that the two ends of the insulation cover 10 and the insulating members 11 do not need to be sealed. Even in the case of gas G entering the space within the insulation cover 10, the space is small and the electron movement distance is short, so plasma P normally does not generate in the space. It is noted that the material of the insulation cover 10 is, for example, quartz, alumina, fluorocarbon resin, silicon nitride, silicon carbide, silicon, or the like.

By providing the insulation cover 10, incidence of charged particles in the plasma P on the metal pipe 31 constituting the antenna 3 may be suppressed, so that an increase in plasma potential due to incidence of charged particles (mainly electrons) on the metal pipe 31 may be suppressed, and metal contamination of the plasma P and the base material W due to sputtering of the metal pipe 31 by charged particles (mainly ions) may be suppressed.

The length of the antenna 3 in the longitudinal direction is preferably 30 cm or more, more preferably 50 cm or more, and even more preferably 100 cm or more from the viewpoint of synthesizing the diamond thin film F over a wider area. On the other hand, from the viewpoint of ensuring the strength of the insulation pipe 32, the length of the antenna 3 is preferably 1000 cm or less, and more preferably 500 cm or less.

Further, the distance between the antenna 3 and the base material W is preferably 100 mm or less, and more preferably 40 mm or more and 60 mm or less, in order to generate uniform plasma P in the longitudinal direction of the antenna 3 within the vacuum vessel 2. Here, in the case of the distance between the antenna 3 and the base material W becoming too close, the electron density and electron temperature increase and graphitization of the thin film occurs, so the distance between the antenna 3 and the base material W is preferably separated by a predetermined distance.

As shown in FIG. 1, the antenna 3 has a power supply terminal part 3a to which high frequency is supplied in the antenna direction (longitudinal direction X), and a grounded grounding terminal part 3b. Specifically, at two ends of each antenna 3 in the longitudinal direction X, a portion extending outward from one sidewall 2a or 2b becomes the power supply terminal part 3a, and a portion extending outward from the other sidewall 2a or 2b becomes the grounding terminal part 3b.

Here, high frequency is applied from the high-frequency power source 4 to the power supply terminal part 3a of each antenna 3 via a matching unit 41. The frequency of the high frequency is 400 kHz or more and 100 MHz or less, and is, for example, a general 13.56 MHz, but is not limited thereto. For example, it may be 27.12 MHz, 40.68 MHz, 60 MHz, or the like.

### Method for Producing Diamond Thin Film

Next, a method for producing the diamond thin film F using the above-described film forming apparatus 100 will be described.

First, the base material W is set on the base material holder 8 in the vacuum vessel 2 of the film forming apparatus 100, and the vacuum vessel 2 is vacuum evacuated by the vacuum exhaust apparatus 6. Then, the base material W is heated by the heater 81, and the temperature of the base material W is preferably set to 100° C. or more and 1200° C. or less.

### Supply of Raw Material Gas

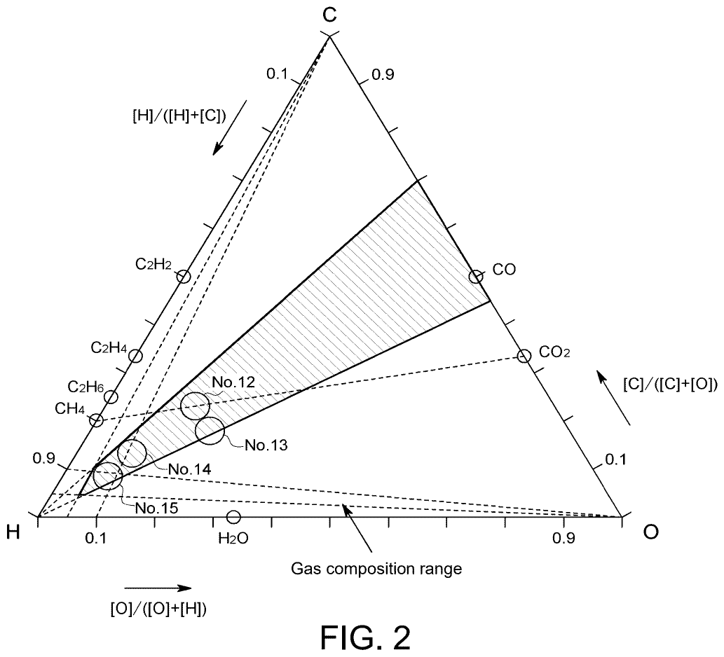

Next, H₂ gas, CH₄ gas, and CO₂ gas as raw material gas are supplied into the vacuum vessel 2 at predetermined flow rates by the gas supply mechanism 7. In the method for producing the diamond thin film F of this embodiment, the flow rates of H₂ gas, CH₄ gas, and CO₂ gas are adjusted so that the atomic number ratio of O atoms, C atoms, and H atoms in the raw material gas falls within the hatched range shown in the composition ternary diagram (C—H—O diagram) of FIG. 2. The atomic number ratio of each atom will be described below.

### Atomic Number Ratio of Oxygen and Hydrogen

In the supplied raw material gas, the flow rates of H₂ gas, CH₄ gas, and CO₂ gas are controlled and supplied so that the ratio of the concentration of O atoms to the total concentration of contained O atoms and H atoms (O/(O+H)) is preferably 5 at % or more and 45 at % or less, more preferably 5 at % or more and 10 at % or less.

### Atomic Number Ratio of Oxygen and Carbon

In the supplied raw material gas, the flow rates of H₂ gas, CH₄ gas, and CO₂ gas are controlled and supplied so that the ratio of the concentration of C atoms to the total concentration of contained O atoms and C atoms (C/(O+C)) is preferably 45 at % or more and 70 at % or less.

### Atomic Number Ratio of Carbon and Hydrogen

Further, in the supplied raw material gas, the flow rates of H₂ gas, CH₄ gas, and CO₂ gas are controlled and supplied so that the ratio of the concentration of H atoms to the total concentration of contained C atoms and H atoms (H/(C+H)) is preferably 60 at % or more and 95 at % or less, more preferably 90 at % or more and 95 at % or less.

### Supply of Catalyst Gas

Furthermore, the gas supply mechanism 7 supplies catalyst gas such as Ar gas into the vacuum vessel 2 together with the raw material gas. The flow rate of the supplied catalyst gas is set so that the ratio to the total flow rate of all gases supplied to the vacuum vessel 2 is preferably 50% or more and 95% or less, more preferably 70% or more and 90% or less. By setting the flow rate of the supplied catalyst gas within such a range, during film formation, energy may be transferred from, for example, easily ionizable Ar to CH₄, and many C₂ radicals that easily generate diamond may be produced. Thereby, in the emission spectrum of the generated inductively coupled plasma, the ratio of the luminescence intensity of C₂ radicals to the luminescence intensity of Hα radicals may be set to 30% or more and 300% or less, more preferably 90% or more and 250% or less.

### Pressure in Vacuum Vessel

Then, while introducing the raw material gas and catalyst gas by the gas supply mechanism 7, the pressure inside the vacuum vessel 2 is adjusted by the pressure regulator 61 to be 7 Pa or more and 100 Pa or less, more preferably 10 Pa or more and 50 Pa or less.

### Generation of Plasma and Film Formation of diamond thin film

Then, in the case of adjusting the flow rates of the raw material gas and catalyst gas as described above and adjusting the pressure inside the vacuum vessel 2, high-frequency power is supplied from the high-frequency power source 4 to the antenna 3. This generates an induced electric field inside the vacuum vessel 2 to generate inductively coupled plasma P, and forms a diamond thin film F on the base material W. It is noted that the frequency of the high-frequency power is 13.56 MHz. The power density of the supplied high-frequency power is preferably 0.1 W/cm² or more, more preferably 0.5 W/cm² or more, and further preferably 1 W/cm² or more. The power density is preferably 1000 W/cm² or less, more preferably 100 W/cm² or less, and further preferably 50 W/cm² or less.

Here, in the case of synthesizing the diamond thin film F, in order to suppress the synthesis of graphite or DLC film, it is necessary to set the plasma characteristics within the following numerical ranges. In the case of the plasma characteristics being within the following numerical ranges, the crystallinity of diamond in the diamond thin film F becomes high, and deterioration of the film quality of the diamond thin film F is suppressed. It is noted that the plasma characteristics referred to here are electron temperature Te, electron density ne, and ion saturation current Iᵢₛ.
Electron temperature Te: 1.0 eV≤Te≤2.0 eV
Electron density ne: 1×10¹¹ cm⁻³≤ne≤1×10¹² cm⁻³
Ion saturation current Iᵢₛ: 1×10⁻⁴A≤Iᵢₛ≤1×10⁻² A

### EXAMPLES

Hereinafter, the present invention will be described more specifically by listing examples. The present invention is not limited by the following examples, and may be implemented with modifications within a range that may conform to the above and below described purposes, and all of these are included in the technical scope of the present invention.

In the examples, samples were formed on substrates in the following three examples and two comparative examples by plasma CVD method using the aforementioned film forming apparatus 100. The pressure in the vacuum vessel 2, input power, distance between the base material and antenna, frequency of supplied high-frequency power, and plasma characteristics during sample manufacturing are as follows.

### Example 1

Pressure in vacuum vessel 2: 15 Pa
Input power: 3.0 kW
Distance between base material W and antenna 3:50 mm
Frequency of supplied high-frequency power: 13.56 MHZ
Electron temperature Te: 1.5 eV
Electron density ne: 7.5×10¹¹ cm⁻³
Ion saturation current Iᵢₛ: 6×10⁻4 A

### Example 2

Pressure in vacuum vessel 2:15Pa
Input power: 3.0 kw
Distance between base material W and antenna 3:30 mm
Frequency of supplied high-frequency power: 13.56 MHz
Electron temperature Te: 1.98 eV
Electron density ne: 7.28×10¹¹cm⁻³
Ion saturation current Iᵢₛ: 1.03×10⁻³ A

### Example 3

Pressure in vacuum vessel 2:15 Pa
Input power: 4.0 kW
Distance between base material W and antenna 3:30 mm
Frequency of supplied high-frequency power: 13.56 MHz
Electron temperature Te: 1.01 eV
Electron density ne: 9.8×10¹¹ cm⁻³
Ion saturation current Iᵢₛ: 2.3×10⁻³ A

### Comparative Example 1

Pressure in vacuum vessel 2:15 Pa
Input power: 2.0 kW
Distance between base material W and antenna 3:50 mm
Frequency of supplied high-frequency power: 13.56 MHz
Electron temperature Te: 1.99 eV
Electron density ne: 1.08×10¹¹cm⁻³
Ion saturation current Iᵢₛ: 9.89×10⁻⁵ A

### Comparative Example 2

Pressure in vacuum vessel 2: 30 Pa
Input power: 2.0 kW
Distance between base material W and antenna 3:10 mm
Frequency of supplied high-frequency power: 13.56 MHz
Electron temperature Te: 1.6 eV
Electron density ne: 2.66×10¹² cm⁻³
Ion saturation current Iᵢₛ: 3.70×10⁻³ A

Here, the electron temperature Te, electron density ne, and ion saturation current Iᵢₛ were measured by a Langmuir Probe, which is a known plasma measurement device.

In Example 1, the crystallinity of the synthesized sample was evaluated by laser Raman spectroscopy (325 nm excitation). As a result, the optical phonon peak of diamond observed in the wavelength vicinity of 1330 cm⁻¹ had an intensity 2.5 times higher compared to the optical phonon peak of the G band observed in the wavelength vicinity of 1550 cm⁻¹, and it was confirmed that a diamond thin film with high diamond crystallinity might be synthesized.

In Example 2, the crystallinity of the synthesized sample was evaluated by laser Raman spectroscopy (325 nm excitation). As a result, the optical phonon peak of diamond observed in the wavelength vicinity of 1330 cm⁻¹ was detected, and the optical phonon peak of the G band observed in the wavelength vicinity of 1550 cm⁻¹ was not detected, so it was confirmed that a diamond thin film might be synthesized.

In Example 3, the crystallinity of the synthesized sample was evaluated by laser Raman spectroscopy (325 nm excitation). As a result, the optical phonon peak of diamond observed in the wavelength vicinity of 1330 cm⁻¹ was detected, and the optical phonon peak of the G band observed in the wavelength vicinity of 1550 cm⁻¹ was not detected, so it was confirmed that a diamond thin film might be synthesized.

In Comparative Example 1, the type of the synthesized sample was evaluated by Raman spectroscopy (325 nm excitation). As a result, the diamond peak (1330 cm⁻¹~1335 cm⁻¹) was not detected, and the D band (1340 cm⁻¹~1380 cm⁻¹) and G band (1510 cm⁻¹~1560 cm⁻¹) were detected, so it was confirmed that the synthesized sample was a DLC film, not a diamond thin film.

In Comparative Example 2, the type of the synthesized sample was evaluated by Raman spectroscopic analysis (325 nm excitation). As a result, the diamond peak (1330 cm⁻¹~1335 cm⁻¹) was not detected, and the G band derived from graphite (1580 cm⁻¹~1620 cm⁻¹) was detected, so it was confirmed that the synthesized sample was graphite, not a diamond thin film.

From the above, in the plasma characteristics in the case of synthesizing a diamond thin film, it was confirmed that a diamond thin film with high diamond crystallinity may be synthesized in the case of an electron temperature of 1.0 eV or more and 2.0 eV or less, an electron density of 1.0×10¹¹ cm⁻³ or more and 1.0×10¹² cm⁻³ or less, and an ion saturation current of 1.0×10⁻⁴ A or more and 1.0×10⁻² A or less.

### Effects of This Embodiment

According to this embodiment, since the antenna 3 having the conductor element 31 and the capacitive element electrically connected in series with each other is used, compared to a configuration using a conventional plasma CVD apparatus, uniform plasma P is generated in the longitudinal direction of the antenna 3, and a diamond thin film F with a wider area may be synthesized.

Further, in the case of the plasma characteristics being within the above numerical range, since the diamond thin film F is synthesized in a state where the electron temperature Te and electron density ne are appropriate, deterioration of the film quality of the diamond thin film F may be prevented.

Specifically, in the case of the electron temperature Te becoming a value greater than the upper limit value, electron collision with the base material W increases and the temperature of the base material W rises excessively, and there is a possibility that graphite may be synthesized. On the other hand, in the case of the electron temperature Te becoming a value less than the lower limit value, sufficient dissociation of the raw material gas has not progressed, and the synthesized thin film becomes a DLC film with many sp bonding or sp2 bonding. Thus, the electron temperature Te needs to be within the above numerical range. Further, regarding the electron density ne, for the same reason as the electron temperature Te, in order to prevent synthesis of graphite or synthesis of a DLC film, the electron density ne needs to be within the above numerical range.

Here, in the synthesis of the diamond thin film F, ionic carbon species (C²⁺, CH₃⁺, CH⁺, etc.) exist in the plasma P. As a result, two phenomena occur simultaneously: (1) secondary nuclei are generated on the diamond by ionic carbon species colliding with the growth surface, and (2) growth of the diamond thin film F is inhibited by the ionic carbon species.

In order to synthesize the diamond thin film F while suppressing these two phenomena, it is necessary to control the ion saturation current Iᵢₛ within the above numerical range. Specifically, in the case of the ion saturation current Iᵢₛ becoming a value greater than the upper limit value, the frequency of ionic carbon species colliding with the base material W increases, and growth inhibition of the diamond thin film F by the ionic carbon species becomes large. As a result, the growth rate of the diamond thin film F decreases, or the film quality of the diamond thin film F deteriorates. On the other hand, in the case of the ion saturation current Iᵢₛ becoming less than the lower limit value, ionic carbon species necessary for growth of the diamond thin film F do not sufficiently exist on the surface of the base material W, and the growth rate of the diamond thin film F decreases. Thus, the ion saturation current Iᵢₛ needs to be within the above numerical range.

Further, according to this embodiment, since the antenna 3 has a length of 30 cm or more in the longitudinal direction and forms a linear shape, a diamond thin film F with a wider area may be uniformly synthesized in the longitudinal direction compared to a configuration using a conventional plasma CVD apparatus.

### Other Embodiments

It is noted that the film forming apparatus 100 of the present invention is not limited to the aforementioned embodiment.

In addition to this embodiment, the method for producing the diamond thin film F applies a bias voltage to the base material W, and may apply a negative bias voltage of −100V or less to the base material W and apply a positive bias voltage of 100V or less to the base material W.

Thereby, by applying a bias voltage to the base material W, the energy when positive ions in the plasma P are incident on the base material W may be controlled, and control of the crystallinity of the film formed on the surface of the base material W may be performed. Specifically, first by applying a negative bias voltage of −100V or less to the base material, formation of diamond growth nuclei is promoted, and after formation of diamond nuclei, by applying a positive bias voltage of 100V or less, growth of the diamond thin film F may be promoted.

In the film forming apparatus 100 of the aforementioned embodiment, the antenna 3 that generates inductively coupled plasma is disposed inside the vacuum vessel 2, but the present invention is not limited thereto. The film forming apparatus 100 of other embodiments may have a structure in which the antenna 3 is disposed outside the vacuum vessel 2.

It goes without saying that the present invention is not limited to the aforementioned embodiments, and various modifications are possible within the scope that does not depart from the spirit thereof. For example, it will be understood by those skilled in the art that the multiple exemplary embodiments described above are specific examples of the following aspects.

### INDUSTRIAL APPLICABILITY

According to the present invention, it is possible to synthesize diamond thin film over a wider area and suppress deterioration of the film quality of the diamond thin film.

### REFERENCE SIGNS LIST

100 . . . Film forming apparatus
2 . . . Vacuum vessel
3 . . . Antenna
7 . . . Gas supply mechanism
F . . . Diamond thin film
W . . . Base material
P . . . Plasma

1. A method for producing a diamond thin film, the method for producing the diamond thin film comprising:
supplying a raw material gas containing C, H, and O into a vacuum vessel in which a base material is disposed;
generating inductively coupled plasma in the vacuum vessel by flowing high-frequency current through an antenna disposed inside or outside the vacuum vessel, the antenna comprising a conductor element and a capacitive element electrically connected to each other in series; and
synthesizing a diamond thin film on the base material by a plasma CVD method using a generated inductively coupled plasma,
wherein plasma characteristics when synthesizing the diamond thin film comprise:
an electron temperature of 1.0 eV or more and 2.0 eV or less,
an electron density of 1.0×10¹¹ cm⁻³ or more and 1.0×10¹² cm⁻³ or less, and
an ion saturation current of 1.0×10⁻⁴ A or more and 1.0×10⁻² A or less.

2. The method for producing the diamond thin film according to claim 1, wherein the antenna has a linear shape and has a length of 30 cm or more in a longitudinal direction.

3. The method for producing the diamond thin film according to claim 1, wherein a distance between the antenna and the base material is 100 mm or less.

4. The method for producing the diamond thin film according to claim 1, wherein the method for producing the diamond thin film applies a bias voltage to the base material, a negative bias voltage of −100V or less is applied to the base material, and a positive bias voltage of 100V or less is applied to the base material.

5. The method for producing the diamond thin film according to claim 1, wherein the raw material gas further contains a noble gas that is Ar, He, or Ne.

6. The method for producing the diamond thin film according to any one of claims 1 claim 1, wherein a high frequency of the high-frequency current has a frequency of 400 kHz or more and 100 MHz or less.

7. An apparatus for producing a diamond thin film, which is an apparatus for producing a diamond thin film for synthesizing a diamond thin film on a base material by a plasma CVD method using inductively coupled plasma, comprising:
a vacuum vessel in which the base material is disposed and to which a raw material gas containing C, H, and O is supplied;
an antenna disposed inside or outside the vacuum vessel and comprising a conductor element and a capacitive element electrically connected to each other in series; and
a high-frequency power source for applying high frequency to the antenna to generate inductively coupled plasma in the vacuum vessel,
wherein plasma characteristics in the vacuum vessel when synthesizing the diamond thin film comprise:
an electron temperature of 1.0 eV or more and 2.0 eV or less,
an electron density of 1.0×10¹¹ cm⁻³ or more and 1.0×10¹² cm⁻³ or less, and an ion saturation current of 1.0×10⁻⁴ A or more and 1.0×10⁻² A or less.

8. The method for producing the diamond thin film according to claim 2, wherein a high frequency of the high-frequency current has a frequency of 400 kHz or more and 100 MHz or less.

9. The method for producing the diamond thin film according to claim 3, wherein a high frequency of the high-frequency current has a frequency of 400 kHz or more and 100 MHz or less.

10. The method for producing the diamond thin film according to claim 4, wherein a high frequency of the high-frequency current has a frequency of 400 kHz or more and 100 MHz or less.

11. The method for producing the diamond thin film according to claim 5, wherein a high frequency of the high-frequency current has a frequency of 400 kHz or more and 100 MHz or less.
